(19) United States
(12) Patent Application Publication
(10) Pub. No.: US 2008/0099921 A1
(43) Pub. Date: May 1, 2008

(54) SEMICONDUCTOR DEVICE AND METHOD OF FABRICATING THE SAME

(75) Inventor: Tomio KATATA, Yokkaichi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/933,668

(22) Filed: Nov. 1, 2007

(30) Foreign Application Priority Data
Nov. 1, 2006 (JP) 2006-297828

(51) Int. Cl. H01L 23/52; H01L 21/4763

(52) U.S. Cl. 257/751; 438/653; 257/E21.495; 257/E23.141

(57) ABSTRACT

A semiconductor device includes a semiconductor substrate including an impurity diffusion region within an upper surface thereof, an insulating film formed on an upper surface of the impurity diffusion region, and a contact plug formed in the insulating film so that the contact plug contacts the impurity diffusion region. The contact plug includes a first conductor layer contacting the upper surface of the impurity diffusion region and a second conductor layer formed on the first conductor layer including copper (Cu) or copper alloy layers, and the first conductor layer including a material which suppresses diffusion of the copper of the second conductor layer to the semiconductor substrate.

### CROSS-REFERENCE TO RELATED APPLICATIONS

This application is based on and claims the benefit of priority from the prior Japanese Patent Application No. 2006-297828, filed on Nov. 1, 2006, the entire contents of which are incorporated herein by reference.

### BACKGROUND OF THE INVENTION

1. Field of the Invention

The present invention relates to a semiconductor device provided with contact plugs electrically connecting a transistor source, drain or a gate to a first layer wire and a method of fabricating the same.

2. Description of the Related Art

Semiconductor devices such as memory devices and logic devices have conventionally been provided with contact plugs which electrically connect a transistor source, drain or gate to first layer wirings including tungsten (W), aluminum (Al) and copper (Cu) wirings. The contact plugs are formed on a silicon substrate on which sources, drains or gates are formed, a silicide layer or a polycrystalline silicon layer.

A contact plug is comprised of a titanium (Ti)/titanium nitride (TiN) layer serving as a barrier metal and a tungsten (W) layer formed on an upper surface of the titanium layer/titanium nitride layer. The titanium layer reduces a spontaneous oxide film existing on the silicon substrate, the silicide layer or the polycrystalline silicon layer and reacts with silicon, thereby forming an ohmic contact. The titanium nitride layer is caused to adhere closely to the titanium layer and the tungsten layer therebetween and serves as a barrier against fluorine (F) of tungsten hexafluoride (WF₆). The tungsten layer is formed on the titanium/titanium nitride layer by chemical vapor deposition (CVD)-tungsten (W). The upper portion of the CVD-titanium is removed by the chemical mechanical polishing (CMP), whereupon the tungsten layer remaining in the contact hole is formed into a tungsten plug.

With miniaturization of devices and increase in an operating speed of a semiconductor device, the resistance of the contact plug as an element of wiring resistance has recently been rendered so large as to be unignorable. As a result, the operating speed of the semiconductor device has adversely been affected by the increased resistance of the contact plug. For example, CVD-W has a specific resistance of 15 μΩ-cm, and the titanium/titanium nitride layer has a higher specific resistance than CVD-W single digit or above. Even when the diameter of the contact hole has been reduced, the titanium/titanium nitride layer serving as the barrier film needs to have a predetermined film thickness. Moreover, since the sectional area of the tungsten plug is reduced even though the tungsten plug has a relatively lower resistance, the resistance of the contact plug is increased.

In order that the resistance of the contact plug may be reduced, an improved contact plug has been considered to be made from aluminum (Al) or copper (Cu) each of which has a specific resistance lower than the CVD-tungsten single digit. In this case, a bulk material of aluminum has a specific resistance of 2.7 μΩ·cm and a bulk material of copper has a specific resistance of 1.7 μΩ·cm. However, each of aluminum and copper has a higher reactivity to a part of the silicon substrate located at the bottom of the contact hole and a silicide layer and further has a higher diffusion speed. Accordingly, even when a barrier is provided, each of aluminum and copper penetrates through the barrier, reacting to the silicon substrate and/or silicide layer. Consequently, each of aluminum and copper as impurity forms an interface state on a boundary face of the insulating film, thereby resulting in problems such as occurrence of threshold voltage (Vth) shift, junction leak or spike. On the other hand, when a film thickness of the barrier metal is increased in order that diffusion of aluminum or copper may be prevented, a rate of barrier metal is increased, whereas a rate of the aluminum or copper each of which has a lower resistivity is increased. This increases the plug resistance, rendering an intended purpose or reduction in the resistance of contact plug unattainable.

As a related technique, for example, U.S. Pat. No. 6,534,866 to Jigish D. Trivedi, et al. discloses reducing resistance of a conductor plug buried in a via. However, the disclosed technique, as it stands, cannot be applied to a contact plug which forms an ohmic contact with the silicon substrate, silicide or polycrystalline silicon.

### BRIEF SUMMARY OF THE INVENTION

Therefore, an object of the present invention is to provide a semiconductor device which can achieve a reduction in the electrical resistance of contact plugs and a method of fabricating the same.

In one aspect, the present invention provides a semiconductor device comprising a semiconductor substrate including an impurity diffusion region within an upper surface thereof, an insulating film formed on an upper surface of the impurity diffusion region, and a contact plug formed in the insulating film so that the contact plug contacts the impurity diffusion region, wherein the contact plug includes a first conductor layer contacting the upper surface of the impurity diffusion region and a second conductor layer formed on the first conductor layer including copper (Cu) or copper alloy layers, and the first conductor layer including a material which suppresses diffusion of the copper of the second conductor layer to the semiconductor substrate.

In another aspect, the invention provides a semiconductor device comprising a semiconductor substrate including an upper surface, a polycrystalline silicon layer formed on the upper surface of the semiconductor substrate, an insulating film formed on the polycrystalline silicon layer, and a contact plug formed in the insulating film so that the contact plug electrically contacts with the polycrystalline silicon layer, the contact plug including a first conductor layer formed on the polycrystalline silicon layer and a second conductor layer formed on the first conductor layer, the second conductor layer including copper (Cu) or copper alloy layers, the first conductor layer including a material which suppresses diffusion of the copper of the second conductor layer or layer to the polycrystalline silicon layer.

### BRIEF DESCRIPTION OF THE DRAWINGS

Other objects, features and advantages of the present invention will become clear upon reviewing the following description of one embodiment with reference to the accompanying drawings, in which:

FIG. 1 is a partial longitudinal section showing a first embodiment of the semiconductor device in accordance with the present invention;

FIGS. 2 to 6 are partial longitudinal sections of the semiconductor device at respective one stage of the fabricating method (Nos. 1 to 5);

FIG. 7 is a partial longitudinal section showing a second embodiment of the semiconductor device in accordance with the present invention;

FIG. 8 is a partial longitudinal section showing a third embodiment of the semiconductor device in accordance with the present invention;

FIG. 9 is a partial longitudinal section of the semiconductor device at one stage of the fabricating method;

FIG. 10 is a partial longitudinal section showing a fourth embodiment of the semiconductor device in accordance with the present invention;

FIGS. 11 to 13 are partial longitudinal sections of the semiconductor device at respective one stage of the fabricating method (Nos. 1 to 3);

FIG. 14 is a partial longitudinal section showing a fifth embodiment of the semiconductor device in accordance with the present invention;

FIG. 15 is a partial longitudinal section showing a sixth embodiment of the semiconductor device in accordance with the present invention; and

FIG. 16 is a partial longitudinal section of the semiconductor device at one stage of the fabricating method.

### DETAILED DESCRIPTION OF THE INVENTION

One embodiment of the present invention will be described with reference to the accompanying drawings. Identical or similar parts are labeled by the same reference symbols throughout the figures. It is noted that the figures illustrate frame formats of the device and the relationship between a thickness and planar dimension, thickness ratio of each layer and the like differ from those of actually fabricated devices.

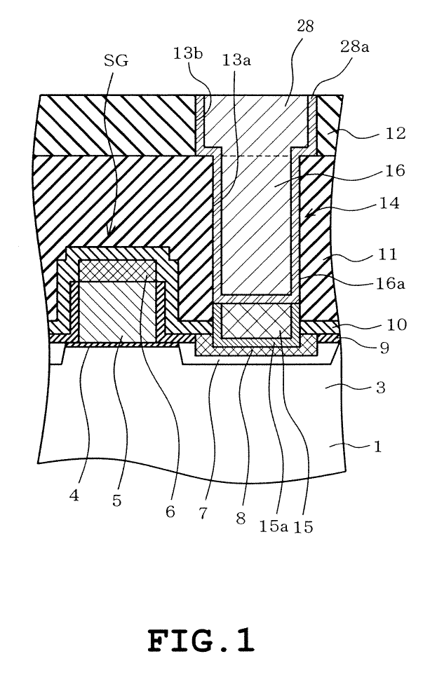

FIG. 1 is a sectional view of a contact of the semiconductor device of a first embodiment. A semiconductor substrate 1 includes an active area 3 on which a gate electrode SG is formed. The gate electrode SG is comprised of a tunnel insulating film 4 formed on the semiconductor substrate 1. A polycrystalline silicon film 5 and a cobalt silicide film 6 are deposited on the tunnel insulating film 4 in turn. Two source/drain regions 7 one of which is shown are formed at both sides of the gate electrode SG respectively. Each source/drain region 7 serves as an impurity diffusion region and is formed by introducing impurities into a surface layer of the substrate 1 by an ion implantation. A cobalt silicide layer 8 is formed on a surface of the source/drain region 7.

A silicon oxide film 9 is formed on a sidewall of the gate electrode SG and the surface of the source/drain region 7 by a rapid thermal processing (RTP) or the like so as to reach a predetermined height with respect to the surface of the semiconductor substrate 1. A silicon nitride film 10 is formed on the upper surfaces of the gate electrode SG and the source/drain region 7. The silicon nitride film 10 serves as an etching stopper. On the silicon nitride film 10 are further formed a silicon oxide film 11 such as a boro-phospho silicate glass (BPSG) film and another silicon oxide film 12 such as a tetraethyl orthosilicate (TEOS) film. A contact hole 13a is formed through the silicon nitride film 10 on the surface of the cobalt silicide layer 8 in the source/drain region 7 and the silicon oxide film 11. An interlayer wiring groove 13b is formed in a silicon oxide film 12 formed over the contact hole 13a so as to communicated with the contact hole 13a. A contact plug 14 is formed in the contact hole 13a so as to be electrically connected to the cobalt silicide layer 8, whereas an interlayer wiring 28 is formed in the groove 13b.

The contact plug 14 has a vertical double layer structure, that is, the contact plug 14 includes a lower layer plug 15 serving as a first conductor layer and an upper layer plug 16 serving as a second conductor layer. The plugs 15 and 16 are formed in the contact hole 13a with barrier metals 15a and 16a being interposed between the plugs and the contact hole. The lower layer plug 15 is filled with tungsten (W) so that a height of the layer plug 5 becomes substantially equal to one third of a height of the contact hole 13a relative to the bottom. The lower layer plug 15 is formed so that an upper surface of the plug is located lower than an upper surface of the polycrystalline silicon film 5 of the adjacent gate electrode. The barrier metal 15a is formed so that a titanium (Ti) layer/titanium nitride (TiN) layer (Ti/TiN layer) covers an upper surface of the cobalt silicide layer 8 and a part of the cobalt silicide layer 8 adjacent to an inner peripheral sidewall thereof a titanium (Ti) layer/titanium nitride (TiN) layer (Ti/TiN layer). Copper (Cu) is buried in the contact hole 13a on the lower plug 15, whereby the upper layer plug 16 is formed. A barrier metal 16a is formed so that a tantalum (Ta) layer or tantalum nitride (TaN) layer (Ta(N) layer) covers an upper surface of the lower layer plug 15 and an inner sidewall of the contact hole 13a.

Copper (Cu) is buried in the groove 13b with a barrier metal layer 28a being interposed between the interlayer wiring 12 and the silicon oxide film 12. The barrier metal layer 28a is comprised of a tantalum (Ta) layer or tantalum nitride (TaN) layer (Ta (N) layer. The interlayer wiring 28 is formed integrally with the upper layer plug 16.

In the foregoing configuration, the upper layer plug 16 is comprised of copper so that the resistance is lowered. The lower layer plug 15 is comprised of tungsten that has a higher melting point than copper. As a result, copper is prevented from diffusion to the silicon substrate 1 side, whereupon electrical characteristics of the transistor can be maintained at desirable values. More specifically, a resistance value of a contact plug made of only a tungsten film is substantially doubled with progress in the refinement of design rules of semiconductor devices. Resistance of the material for the contact plug needs to be reduced by half in order that the increase in the resistance value may be suppressed. For this purpose, the tungsten film needs to have a height that is no more than one third of a height of the contact hole. However, when 50 nm or more film thickness of the tungsten film is ensured, the copper of the upper layer copper plug 16 can be prevented from diffusion to the silicon substrate 1 side. Furthermore, when copper is buried in the contact hole 13, an aspect ratio can be reduced since the lower layer plug 15 is previously formed. Consequently, the contact plug 14 can easily be formed without occurrence of void.

Furthermore, the upper plug 16 comprised of copper (Cu) having as a bulk material a specific resistance of 1.7 μΩ-cm occupies most part of the interior of the contact hole 13. Consequently, the resistance of the contact plug can be reduced to the value that is one half to one fourth of the contact plug resistance in the case where the contact plug is comprised of only tungsten (W).

Since the barrier metal layer 16a is provided between the upper and lower plug layers 16 and 15, copper (Cu) of the upper layer plug 16 and tungsten (W) can be prevented from being formed into an alloy.

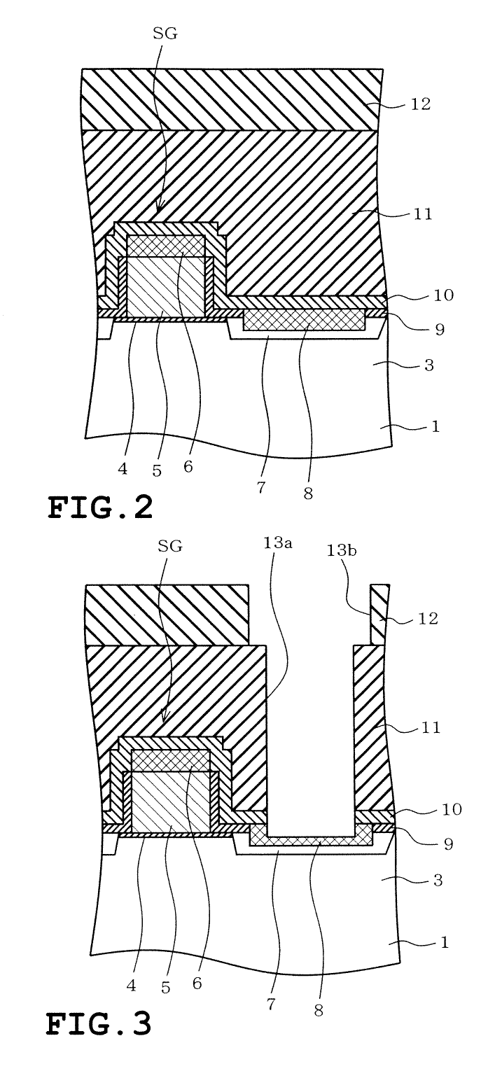

A fabricating process of the foregoing configuration will now be described with reference to FIGS. 2 to 6. FIG. 2 illustrates the state of the semiconductor device before the forming of the contact hole 13a and the groove 13b. The process to obtain the semiconductor device as shown in FIG. 2 will be described in brief. The tunnel insulating film 4 is formed on the silicon substrate 1. Subsequently, the polycrystalline silicon film 5 composing the gate electrode SG is formed on the tunnel insulating film 4. Next, an oxidation treatment is carried out by RTP or the like so that the silicon oxide film 9 is formed on the sidewall of the gate electrode SG. Subsequently, the source/drain region 7 is formed by an ion implantation treatment and then, a process is carried out to expose an upper part of the polycrystalline silicon film 5 and a part of the surface of the source/drain region 7, and the cobalt film is formed. A thermal treatment is then carried out to form the cobalt silicide (CoSi₂) layers 6 and 8. Thereafter, the silicon nitride film 10 is formed so as to cover the gate electrode SG and the surface of the silicon substrate 1. The silicon nitride film 10 serves as an etching stopper in the case where the contact hole 13a is formed. Furthermore, the BPSG film is formed as the silicon oxide film 11. After execution of the planarizing process, the silicon oxide film 12 such as the TEOS film is formed. Thus, the device assumes the state as shown in FIG. 2.

Subsequently, as shown in FIG. 3, the photolithography process is carried out so that the groove 13b is formed in the silicon oxide film 12 and the contact hole 13a is formed in the silicon oxide film 11. In this case, the contact hole 13a is formed by etching with the silicon nitride film 10 serving as the etching stopper while the selective gate is raised under the condition where the silicon nitride film 11 is etched by the reactive ion etching (RIE) process. When the silicon nitride film 10 has been exposed, the etching condition is changed so that the selective ratio of the silicon nitride film 10 is increased, whereby the cobalt silicide layer 8 is exposed.

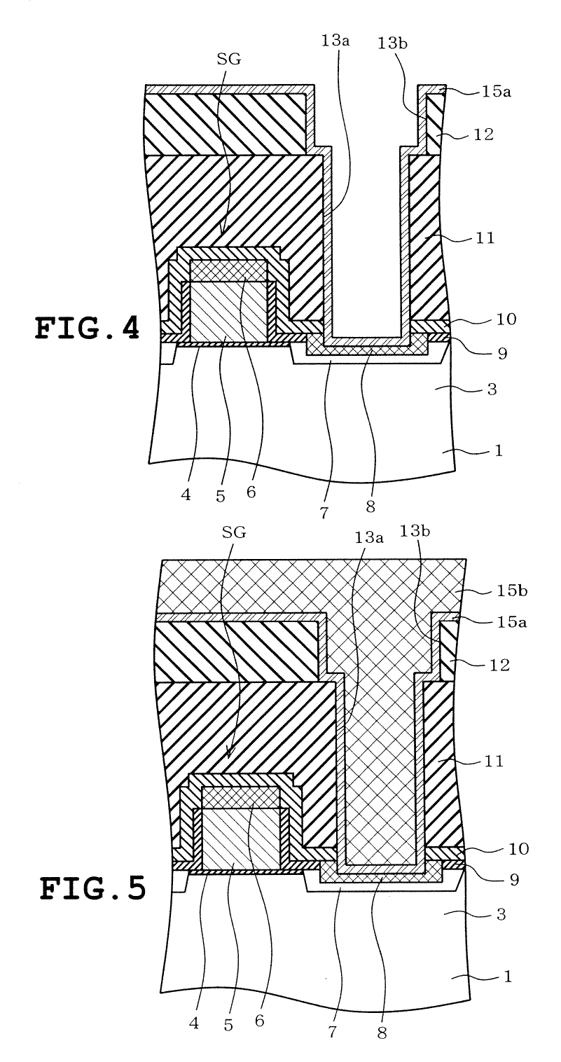

Subsequently, as shown in FIG. 4, the barrier metal layer 15a is formed so as to cover the inner peripheral wall surfaces of the contact hole 13a and the groove 13b in order to increase the adhesion with the lower layer plug 15 and in order to prevent reaction between tungsten and the silicon substrate 1. In forming the barrier metal layer 15a, for example, an IMP-titanium/MOCVD-titanium nitride film is formed and then annealed using a forming gas (nitrogen/hydrogen mixed gas at 550° C. “IMP” stands for ionized metal plasma and “MOCVD” stands for metal organic chemical vapor deposition.

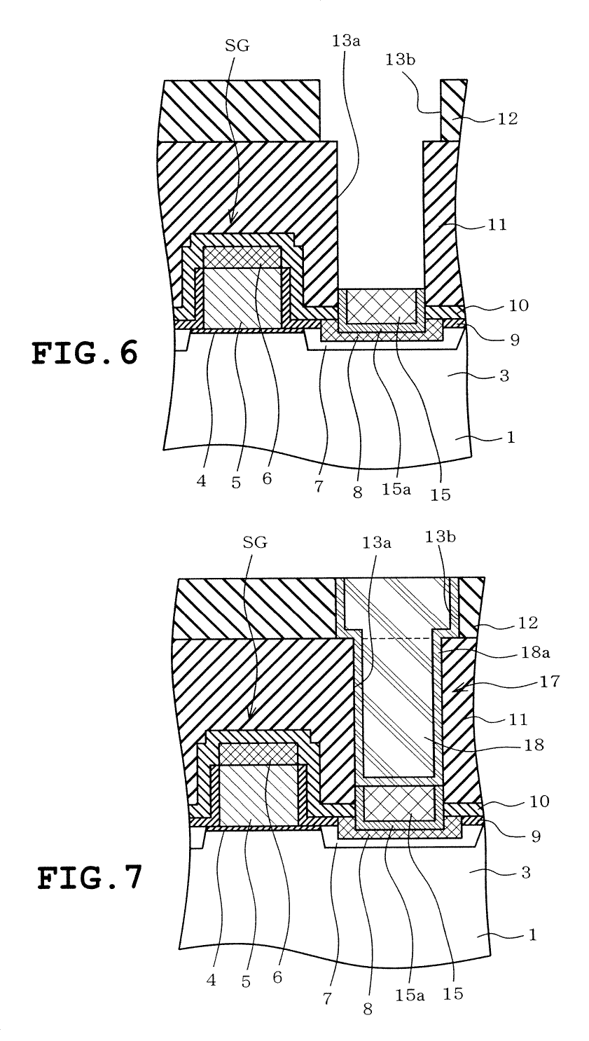

Subsequently, as shown in FIG. 5, the CVD-tungsten (W) film 15b is formed on the whole surface so as to bury the contact hole 13a and the groove 13b. Thereafter, as shown in FIG. 6, the whole surface is etched by the RIE method so that each of the tungsten film 15b and the barrier metal layer 15a has a height that is about one third of the height of the contact hole. Subsequently, a tantalum (Ta) layer or tantalum nitride (TaN) layer and a copper seed are formed by the physical vapor deposition (PVD) method as a barrier metal layer 16a of the upper player plug 16 and a barrier metal layer 28a of an interlayer wiring 28, so as to cover the exposed inner peripheral wall surface of the contact hole 13a and the inner peripheral wall surface of the groove 13, respectively. Thereafter, a copper layer is deposited on the whole silicon substrate 1 surface including the inside of the contact hole 13a and the inside of the groove 13b by an electroplating method. After execution of a thermal treatment, the Cu layer and the Ta (N) layer 16a deposited outside the groove 13b and inside the silicon oxide film 12 are polished by the CMP method, whereupon the low resistance contact plug 14 and interlayer wiring 28 are completed in which one half or more of the groove 13b and the contact hole 13a are filled with the Cu layer.

According to the above-described fabricating process, the lower layer plug 15 has already been buried in the contact hole 13a when the upper layer plug 16 is formed. As a result, an aspect ratio of the contact hole 13a can be rendered smaller and accordingly, a degree of difficulty in the burying such that the contact hole can be buried while occurrence of void is suppressed.

FIG. 7 illustrates a second embodiment of the invention. The second embodiment differs from the first embodiment in the provision of a contact plug 17, instead of the contact plug 14. The material for the contact plug 17 differs from the material for the contact plug 14 although the contact plug 17 has the same structure as the contact plug 14.

The same tungsten (W) layer as in the first embodiment is used for the lower layer plug 15 of the contact plug 17. An upper plug 18 is comprised of an aluminum-copper alloy (AlCu) layer as the copper alloy serving as the lower resistance material. A film of three-layer structure or a titanium (Ti) layer/titanium nitride (TiN) layer/titanium layer is formed by the physical vapor deposition (PVD) method. Next, a MOCVD-aluminum (Al) is formed as a liner. Thereafter, an aluminum-copper alloy (AlCu) is formed and buried by the PVD method while the substrate is heated at about 400° C. Subsequently, the dual damascene structure is realized by the CMP method.

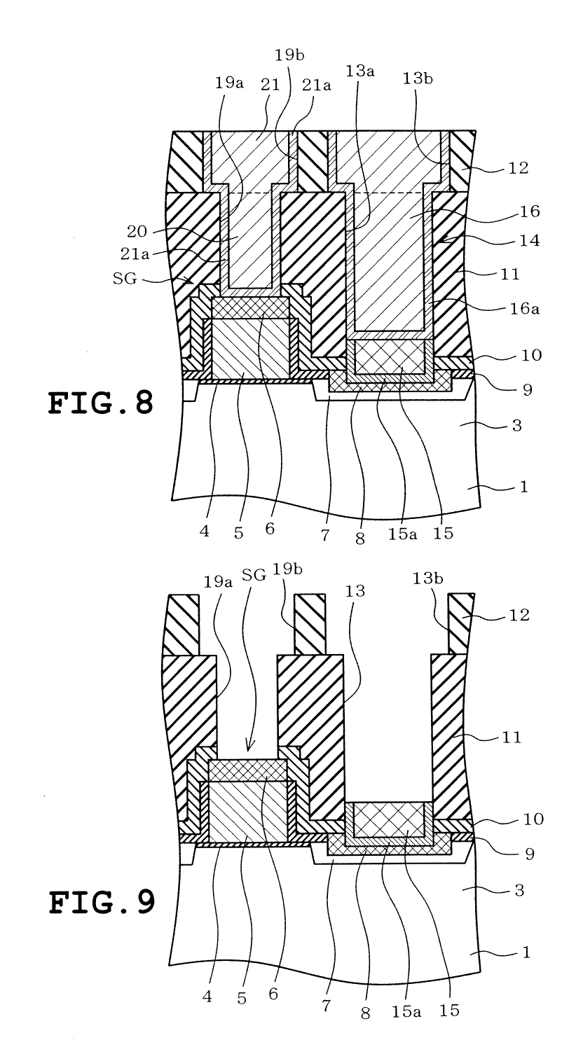

FIGS. 8 and 9 illustrate a third embodiment of the invention. The third embodiment differs from the first embodiment in an additional contact hole 19a formed at the cobalt silicide layer 6 side of the gate electrode SG for provision of a contact plug 20. Although FIG. 8 shows the contact plug 14 of the source/drain region 7 and the contact plug 20 of the gate electrode SG both adjacent to each other, both contact plugs 14 and 20 may be spaced from each other. In each case, both contact plugs 14 and 20 are formed by the same process in the second embodiment.

The contact plug 20 electrically connected to the cobalt silicide layer 6 composing an upper part of the gate electrode SG has the same configuration as the upper layer plug 16 of the contact plug 14. The tantalum (Ta) layer or tantalum nitride (Ta (N)) layer covers the bottom and sidewall of the contact hole 19 and copper (Cu) serving as a conductor layer is buried in the contact hole 19.

The fabricating process of the foregoing configuration will be described. Steps of the fabricating process in the third embodiment are substantially the same as described in the first embodiment. However, when the contact hole 13a and the groove 13b are formed as shown in FIG. 5, the contact hole 19a and the interlayer wiring groove 13b are simultaneously formed as shown in FIG. 9. Thereafter, the barrier metal layers 15a and 21a are formed on the contact hole 13a and the groove 13b, and the contact hole 19a and inner peripheral wall surface of the groove 13b in the same manner as described above, respectively. The IMP-titanium (Ti)/MOCVD-titanium nitride film is formed and annealed using a forming gas at 550° C. Subsequently, the tungsten film 15b is formed in the contact hole 13a, groove 13b, contact hole 19a and groove 13b in the same manner as described above.

Subsequently, as shown in FIG. 9, the whole surface of the tungsten film 15b is etched by the RIE method so that the tungsten film 15b is higher than the surface of the silicon substrate 1 and lower than the upper surface of the gate electrode SG and so that the tungsten film 15b has a height that is about one third of the depth or the vertical dimension of the contact hole. In this case, since the contact hole 19a at the gate electrode SG side is shallower than the contact hole 13, all the tungsten film 15b in the contact hole 19a is removed by the etching when the tungsten film 15b is rendered thinner with progress of etching. Thus, the same steps are carried out so that the configuration as shown in FIG. 8 is obtained.

Since the above-described fabricating process is employed, the lower layer plug 15 has already been buried in the contact hole 13a when the upper layer plug 16 is formed. As a result, an aspect ratio of the contact hole 13a can be rendered smaller and accordingly, a degree of difficulty in the burying such that the contact hole can be buried while occurrence of void is suppressed.

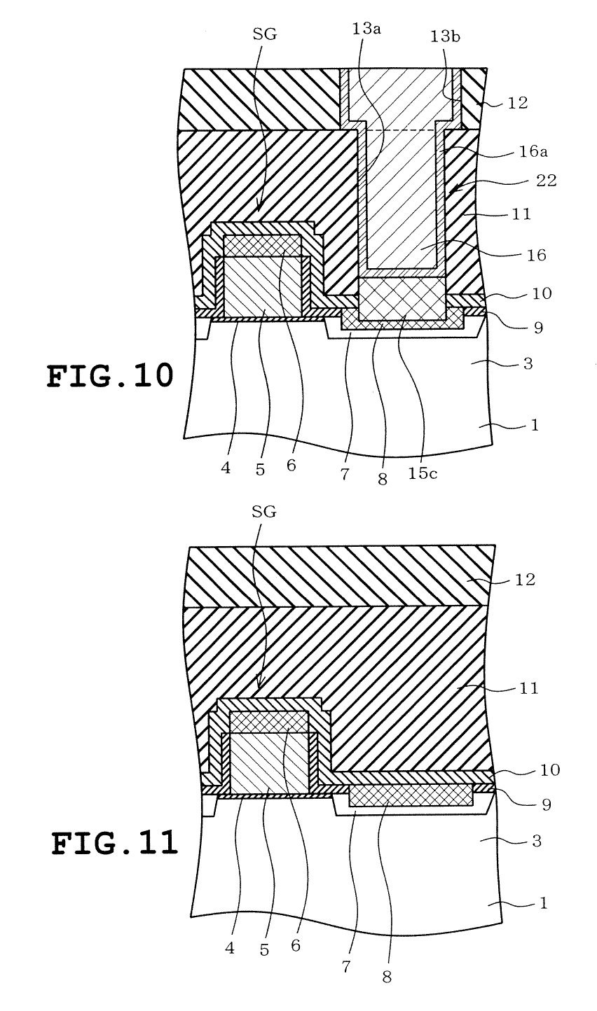

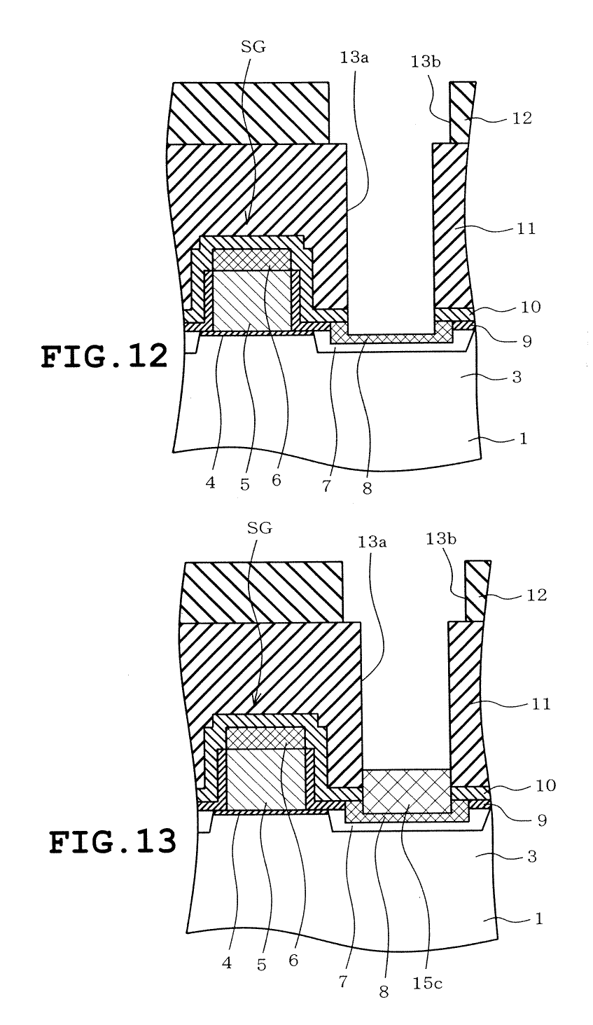

FIGS. 10 to 13 illustrate a fourth embodiment of the invention. The fourth embodiment differs from the first embodiment in the provision of a contact plug 22, instead of the contact plug 14. As shown in FIG. 10, the lower layer plug 15c of the contact plug 22 is comprised of a tungsten film as in the first embodiment. However, the lower plug 15c is provided so as to be in direct contact with the source/drain region 7 without provision of the barrier metal layer. The contact plug 22 is formed by the fabrication process different from that of the contact plug 14 in the first embodiment although both contact plugs can achieve substantially the same electrical characteristics.

The fabrication process for the above-mentioned configuration includes a step as shown in FIG. 11 after the same previous steps as in the first embodiment and a step as shown in FIG. 12. The contact hole 13a and the groove 13b are formed in the state as shown in FIG. 11 and the fabrication sequence progresses to FIG. 12. In the state as shown in FIG. 12, the source/drain region 7 of the silicon substrate 1 is exposed only on the bottom of the contact hole 13b, and the other part is covered with the insulating films such as the silicon oxide films 11 and 12. Since a technique (selective CVD-W method) of growing the tungsten film only in the conductive layer is applicable to the condition, a tungsten film is selectively grown only on the bottom of the contact hole 13a so as to have a predetermined film thickness. The tungsten film has a film thickness that is no more that one third of the depth of the contact hole 13a and about 50 nm. The employment of the selective CVD-W method can eliminate the step of forming a barrier metal, the annealing step or the step of leaving the tungsten film only on the bottom of contact hole 13a, thereby reducing the fabrication cost.

Subsequently, as shown in FIG. 10, an atomic layer deposition-ruthenium (Ru) layer (ALD-Ru layer) is formed, and copper is then formed directly on the ruthenium layer by the direct plating method using no seed. The ALD-RU layer serves as a copper barrier metal 16a used for the upper layer plug 16. Next, a copper film is formed directly on the ruthenium layer by a direct plating method without use of seed so as to be deposited the whole wafer including the contact hole 13b and the groove 13b. Then, a thermal treatment is carried out, and the copper layer and ruthenium layer both deposited outside the groove 13b are polished by the CMP method so that the upper layer plug 16 including the groove 13b and the contact hole 13a whose one half or more part is filled with copper is formed, whereby the low resistance contact and wiring are obtained.

In the fourth embodiment, the thin film ruthenium layer is used as the copper barrier metal layer 16a, and the direct plating method necessitating no copper seed is used. Accordingly, the above-described method can cope with refinement of design rules. Consequently, a larger opening diameter of the contact hole 13a before copper plating can be ensured as compared with the method of forming the barrier metal layer and copper seed with the use of PVD method. Copper can be buried even when the method is applied to microscopic contacts.

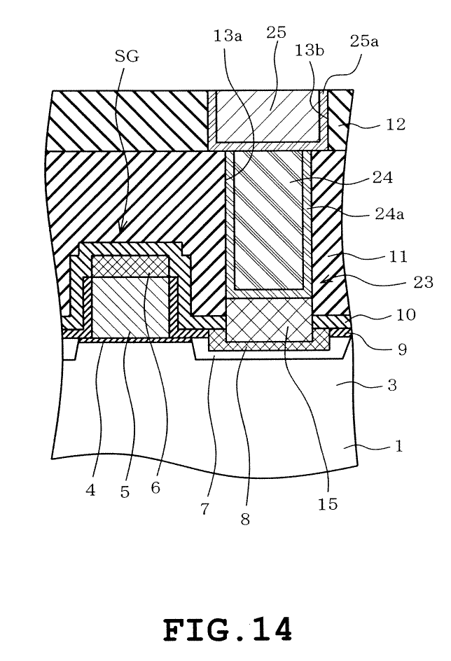

FIG. 14 illustrates a fifth embodiment of the invention. The fifth embodiment differs from the fourth embodiment in that the contact plug 23 and the interlayer wiring 25 are separate from each other. In the fourth embodiment, the copper layer is formed simultaneously on the contact hole 13a and the groove 13b, whereby the contact plug 22 and the interlayer wire are formed. Thus, the fabrication process employs the dual damascene method in the fourth embodiment. On the other hand, the fifth embodiment employs a step of forming the lower layer plug 15 and upper layer plug 24 in the contact hole 13a and a step of forming an interlayer wiring 25 in the groove 13b.

In FIG. 14, the tungsten film is selectively formed without provision of the barrier metal layer regarding the lower layer plug 15. Regarding the upper layer plug 24, however, the barrier metal layer 24a is comprised of a three-layer film of titanium (Ti) layer/titanium nitride (TiN) layer/titanium (Ti) layer. An aluminum or aluminum-copper alloy metal film is formed inside the three-layer film. The interlayer wiring plug 25 formed in the groove 13b is includes a tantalum nitride (Ta(N)) layer serving as the barrier metal layer 25a and copper buried inside the layer 25a.

In the fabrication process of the above-described configuration, a single damascene method is carried out in two parts so that the contact plug 23 and the interlayer wiring 25 are formed. At a first single damascene step, the silicon oxide film 11 is formed and thereafter, the contact hole 13a and the groove 13b are formed. In this state, the tungsten film is formed by the selective growth method in the same manner as in the fourth embodiment. Subsequently, the barrier metal layer 24a is formed and the aluminum or aluminum-copper alloy film is buried. The upper layer plug 24 is then formed in the contact hole 13a by the CMP method. At a second single damascene step, the silicon oxide film 12 is formed, and the interlayer wiring groove 13b is formed in the silicon oxide film 12. The barrier metal layer 25a and the copper layer are then formed, and the interlayer wiring 25 is formed in the groove 13b by the CMP method.

Since the single damascene process is carried out in two divided parts in the fifth embodiment, the aspect ratio at the time of the burying step is rendered smaller than in the dual damascene process. As a result, the burying step can be carried out without occurrence of void even in a refined structure. Although tungsten and aluminum or an aluminum-copper alloy are buried in the contact hole 13a in the fifth embodiment, copper may be buried, instead. Furthermore, aluminum or an aluminum-copper alloy may be used as the material for the interlayer wiring 25 or the conventional Al-RIE wiring with use of the RIE method may be used.

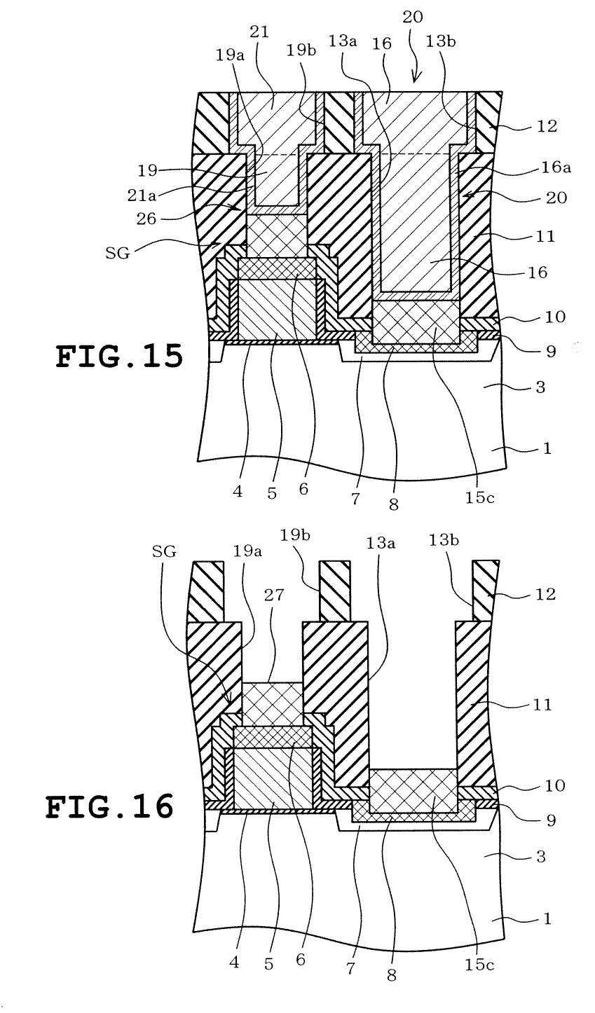

FIGS. 15 and 16 illustrate a sixth embodiment of the invention. In the sixth embodiment, the configuration of the third embodiment is applied to the fourth embodiment. More specifically, as shown in FIG. 15, a contact plug 26 having the same structure as the contact plug 20 is provided so as to correspond to the gate electrode SG. Differing from the fourth embodiment, the sixth embodiment includes a contact plug 26 of the gate electrode SG including a lower layer plug 27 comprised of a tungsten layer and the upper layer plug 19 comprised of the barrier metal layer 21a and the copper layer.

In the fabrication process of the above-described configuration, the contact holes 13a and 19a and the grooves 13b and 19b are formed and thereafter, the selective CVD-W method is employed so that the tungsten film with a predetermined film thickness is selectively formed only in the contact holes as shown in FIG. 16. As a result, the lower layer plugs 15c and 27 are formed in the respective contact holes 13a and 21a. Thereafter, the barrier metal layers 16a and 21a are formed and the copper layer is then formed and thereafter, the upper layer plugs 16 and 19 and the interlayer wirings 21 and 28 are formed in the respective contact holes 13a and 19a and the grooves 13b and 19b by the CMP method.

The invention should not be limited to the foregoing embodiments. The embodiments may be modified or expanded as follows. The cobalt silicide layers 6 and 8 are employed as the silicide layers formed in the upper part of the gate electrode SG and the source/drain region in the first embodiment. However, nickel silicide (NiSi) layers or the like may be employed, instead.

Furthermore, the foregoing embodiments employ salicide in which the cobalt silicide layers 6 and 8 are simultaneously formed in the upper part of the gate electrode SG and the source/drain region 7 in a self-aligning manner respectively in the foregoing embodiments. The salicide is not indispensable. The silicide layer may be formed in one of the two or the invention may be applied to the case other than the self-aligning silicide.

In the step of etching the whole surface of the CVD-tungsten film 15b, polishing may be carried out by the CMP method until the interlayer wiring layer before etching and thereafter, the etching by the RIE method may be carried out, instead. Furthermore, the Ti/TiN layer of the barrier metal layer 15a which is closely adherent to tungsten of the lower layer plug 15 and may be etched together with the lower layer plug 15 or remain in the groove 13b and on the sidewall of the contact hole 13a.

The film thickness of the tungsten layer of the lower layer plug 15 is set at 50 nm in the foregoing embodiments. The value does not show the lower limit value of the film thickness. The tungsten layer of the lower layer plug 15 may be further thinner only if copper of the upper layer plug 16 can be prevented from diffusion into the silicon substrate 1.

The invention may be applied to nonvolatile semiconductor memory devices including NAND flash memories and NOR flash memories, logic semiconductor devices or semiconductor devices with respective contact plugs.

The two-step burying including MOCVD-Al and PVD-Al is carried out so that the AlCu layer is buried. However, a two-step PVD method using directional PVD method such as long throw sputtering may be employed or only MOCVD-Al may be employed for all burying operations, instead.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor device comprising:
a semiconductor substrate including an impurity diffusion region within an upper surface thereof;
an insulating film formed on an upper surface of the impurity diffusion region; and
a contact plug formed in the insulating film so that the contact plug contacts the impurity diffusion region,
wherein the contact plug includes a first conductor layer contacting the upper surface of the impurity diffusion region and a second conductor layer formed on the first conductor layer including copper (Cu) or copper alloy layers, and the first conductor layer including a material which suppresses diffusion of the copper of the second conductor layer to the semiconductor substrate.

2. The device according to claim 1, wherein the first conductor layer includes a tungsten (W) layer.

3. The device according to claim 2, wherein the first conductor layer includes a first barrier metal layer formed on a first barrier metal layer formed on a first side surface and a first bottom surface of the tungsten layer.

4. The device according to claim 2, wherein the first barrier metal layer includes a titanium (Ti) layer.

5. The device according to claim 1, wherein the second conductor layer includes a second barrier metal layer formed on a second side surface and a second bottom surface of the copper or the copper alloy layers.

6. The device according to claim 5, wherein the second barrier metal layer includes a tantalum (Ta) layer.

7. The device according to claim 1, wherein the impurity diffusion region includes a silicide layer contacting with the contact plug.

8. The device according to claim 7, wherein the silicide layer includes a cobalt silicide layer.

9. A semiconductor device comprising:
a semiconductor substrate including an upper surface;
a polycrystalline silicon layer formed on the upper surface of the semiconductor substrate;
an insulating film formed on the polycrystalline silicon layer; and
a contact plug formed in the insulating film so that the contact plug electrically contacts with the polycrystalline silicon layer, the contact plug including a first conductor layer formed on the polycrystalline silicon layer and a second conductor layer formed on the first conductor layer, the second conductor layer including copper (Cu) or copper alloy layers, the first conductor layer including a material which suppresses diffusion of the copper of the second conductor layer or layer to the polycrystalline silicon layer.

10. The device according to claim 9, wherein the first conductor layer includes tungsten (W) layer.

11. The device according to claim 9, wherein the second conductor layer includes a barrier metal layer formed on a side surface and a bottom surface of the copper or the copper alloy layers.

12. The device according to claim 9, wherein the barrier metal layer includes a tantalum (Ta) layer.

13. The device according to claim 9, wherein the polycrystalline silicon layer includes a silicide layer contacting with the contact plug.

14. The device according to claim 13, wherein the silicide layer includes a cobalt silicide layer.

15. A method of fabricating a semiconductor device, comprising:
forming an impurity diffusion region in a surface of a semiconductor substrate;
forming an insulating film on the impurity diffusion region;
partially removing the insulating film thereby to form a contact hole reaching the impurity diffusion region;
burying a first conductor layer in the contact hole to a predetermined depth; and
burying a second conductor layer having copper or a copper alloy, wherein the first conductor layer suppresses diffusion of copper from the second conductor layer to the semiconductor substrate.

16. The method according to claim 15, wherein in the first conductor layer burying step, the whole contact hole is filled with the first conductor film and thereafter, the first conductor layer is removed by an etchback process to a predetermined depth in the contact hole.

17. The method according to claim 15, further comprising forming a barrier metal layer between the first conductor and the insulating film.

18. The method according to claim 15, further comprising forming a barrier metal layer between the second conductor layer and the insulating film.

19. The method according to claim 15, further comprising forming a silicide layer on the impurity diffusion region contacting with the first conductor layer via the barrier metal layer.

20. The method according to claim 15, further comprising:
forming a polycrystalline silicon layer on the semiconductor substrate;
forming an additional contact hole in the insulating film so that the polycrystalline silicon layer is exposed;
burying the first conductor layer in the additional contact hole to the predetermined depth; and
burying the second conductor layer on the first conductor layer in the additional contact hole.
